(19) United States
(12) Patent Application Publication
(10) Pub. No.: US 2025/0053064 A1
(43) Pub. Date: Feb. 13, 2025

(54) OPTICAL DEVICES AND METHODS OF MANUFACTURE

(71) Applicant: Taiwan Semiconductor Manufacturing Co., Ltd., Hsinchu (TW)

(72) Inventors: Su-Chun Yang, Hsinchu (TW); Chen Chiang Yu, Taoyuan City (TW); Jui Hsuan Tsai, Taipei City (TW); Jih-Churng Twu, Hsinchu (TW); Chung-Shi Liu, Hsinchu (TW); Chen-Hua Yu, Hsinchu (TW)

(21) Appl. No.: 18/448,337

(22) Filed: Aug. 11, 2023

(51) Int. Cl. G02F 1/355; G02F 1/35

(52) U.S. Cl. CPC G02F 1/3551; G02F 1/3501; G02F 2201/12; G02F 2202/20; G02F 2203/50

(57) ABSTRACT

Optical devices and methods of manufacture are presented in which a non-linear material is deposited or otherwise placed. Once the non-linear material has been deposited, implantation regions are formed within the non-linear material using an implantation process. The implantation regions are removed using an etching process, and electrodes are formed to the remaining material.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a non-linear optical material, in accordance with some embodiments.

FIG. 2 illustrates placement of a first photoresist, in accordance with some embodiments.

FIG. 3 illustrates an implantation process, in accordance with some embodiments.

FIG. 4 illustrates an etching process, in accordance with some embodiments.

FIG. 5 illustrates deposition of a cladding material, in accordance with some embodiments.

FIG. 6 illustrates formation of conductive elements, in accordance with some embodiments.

FIG. 7 illustrates a singulation process, in accordance with some embodiments.

FIG. 8 illustrates a bonding process, in accordance with some embodiments.

FIG. 9 illustrates a second singulation process, in accordance with some embodiments.

FIG. 10 illustrates a bonding process, in accordance with some embodiments.

FIG. 11 illustrates a removal of a substrate, in accordance with some embodiments.

FIG. 12 illustrates placement of a second photoresist, in accordance with some embodiments.

FIG. 13 illustrates an etching process, in accordance with some embodiments.

FIG. 14 illustrates an implantation process, in accordance with some embodiments.

FIG. 15 illustrates an etching process, in accordance with some embodiments.

FIG. 16 illustrates deposition of a cladding material, in accordance with some embodiments.

FIG. 17 illustrates formation of conductive elements, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which one or more optical phase shifters are manufactured and connected to a photonic integrated circuit platform. However, the specific embodiments presented below are intended to be illustrative of the ideas presented, and the specific embodiments are not intended to limit the ideas. All embodiments that incorporate the ideas presented are fully intended to be included within the scope of the application.

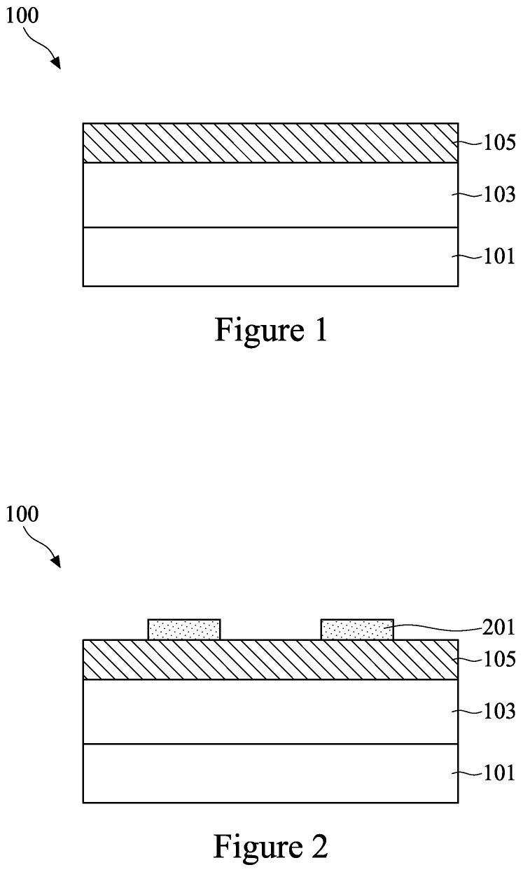

With reference now to FIG. 1, there is illustrated an initial structure of a first optical device 100, in accordance with some embodiments. In the particular embodiment illustrated in FIG. 1, the first optical device 100 is a photonic integrated circuit (PIC) and comprises at this stage a first substrate 101, a first insulator layer 103, a first active layer of first optical components (not separately illustrated in FIG. 1), and a layer of non-linear optical material 105. In an embodiment, at a beginning of the manufacturing process of the first optical device 100, the first substrate 101, the first insulator layer 103, and the layer of material for the first active layer of first optical components may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices. In particular embodiments, the first substrate 101 may be a 4″, 6″, 8″ or 12″ wafer with a thickness of about 100 μm, although any suitable size or shape may be utilized.

The first insulator layer 103 may be a dielectric layer that separates the first substrate 101 from the overlying first active layer and can additionally, in some embodiments, serve as a portion of cladding material that surrounds the subsequently manufactured first optical components (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. The first insulator layer 103 may be deposited to a thickness of about 4 μm. However, any suitable material, thickness and method of manufacture may be used.

The material for the first active layer is initially (prior to patterning) a conformal layer of material that will be used to begin manufacturing the first active layer of the first optical components. In an embodiment the material for the first active layer may be a translucent material that can be used as a core material for the desired first optical components, such as a semiconductor material such as silicon, germanium, silicon germanium, combinations of these, or the like, while in other embodiments the material for the first active layer may be a dielectric material such as silicon nitride or the like, although in other embodiments the material for the first active layer may be III-V materials, lithium niobate materials, or polymers. In embodiments in which the material of the first active layer is deposited, the material for the first active layer may be deposited using a method such as epitaxial growth, chemical vapor deposition, atomic layer deposition, physical vapor deposition, combinations of these, or the like. In other embodiments in which the first insulator layer 103 is formed using an implantation method, the material of the first active layer may initially be part of the first substrate 101 prior to the implantation process to form the first insulation layer 103. However, any suitable materials and methods of manufacture may be utilized to form the material of the first active layer.

Once the material for the first active layer is ready, the first optical components for the first active layer are manufactured using the material for the first active layer. In embodiments the first optical components of the first active layer may include such components as optical waveguides (e.g., ridge waveguides, rib waveguides, buried channel waveguides, diffused waveguides, etc.), couplers (e.g., grating couplers, edge couplers, etc.), directional couplers, optical modulators (e.g., Mach-Zehnder silicon-photonic switches, microelectromechanical switches, micro-ring resonators, etc.), amplifiers, multiplexors, demultiplexers, optical-to-electrical converters (e.g., P-N junctions), electrical-to-optical converters, lasers, combinations of these, or the like. However, any suitable first optical components may be used.

To begin forming the first active layer of first optical components from the initial material, the material for the first active layer may be patterned into the desired shapes for the first active layer of first optical components. In an embodiment the material for the first active layer may be patterned using, e.g., one or more photolithographic masking and etching processes. However, any suitable method of patterning the material for the first active layer may be utilized. For some of the first optical components, such as waveguides or edge couplers, the patterning process may be all or at least most of the manufacturing that is used to form these first optical components.

For those components that utilize further manufacturing processes, such as Mach-Zehnder silicon-photonic switches that utilize resistive heating elements, additional processing may be performed either before or after the patterning of the material for the first active layer. For example, implantation processes, additional deposition and patterning processes for different materials (e.g., resistive heating elements, III-V materials for converters), combinations of all of these processes, or the like, can be utilized to help further the manufacturing of the various desired first optical components. In a particular embodiment, in some embodiments an epitaxial deposition of a semiconductor material such as germanium (used, e.g., for electricity/optics signal modulation and transversion) may be performed on a patterned portion of the material of the first active layer. In such an embodiment the semiconductor material may be epitaxially grown in order to help manufacture, e.g., a photodiode for an optical-to-electrical converter. All such manufacturing processes and all suitable first optical components may be manufactured, and all such combinations are fully intended to be included within the scope of the embodiments.

The non-linear optical material 105 is formed after the first optical components. In an embodiment the non-linear optical material 105 is an electro-optic material with a strong Pockels effect (e.g., a change in the refractive index that is propositional to the electric field strength), such as lithium niobate (LiNbO₃), barium titanate (BaTiO₃-BTO), lead zirconate titanate (PZT), combinations of these, or the like. The non-linear optical material 105 may be deposited using a process such as molecular beam epitaxy (MBE), physical vapor deposition (PVD), thin film transfer by wafer-to-wafer bonding or chip-to-wafer bonding, combinations of these, or the like, to a thickness of between about 0.3 μm and about 1 μm, such as about 600 nm. However, any suitable materials, processes, and thicknesses may be utilized.

FIG. 2 illustrates a placement and patterning of a first photoresist 201 over the non-linear optical material 105. In an embodiment the first photoresist 201 may be one or more layers of masks such as a layer of amorphous silicon and a layer of a photosensitive material. Once in place the photosensitive material is imaged and developed, the underlying layers are patterned, and the remaining portions become the patterned first photoresist 201. However, any suitable process may be utilized.

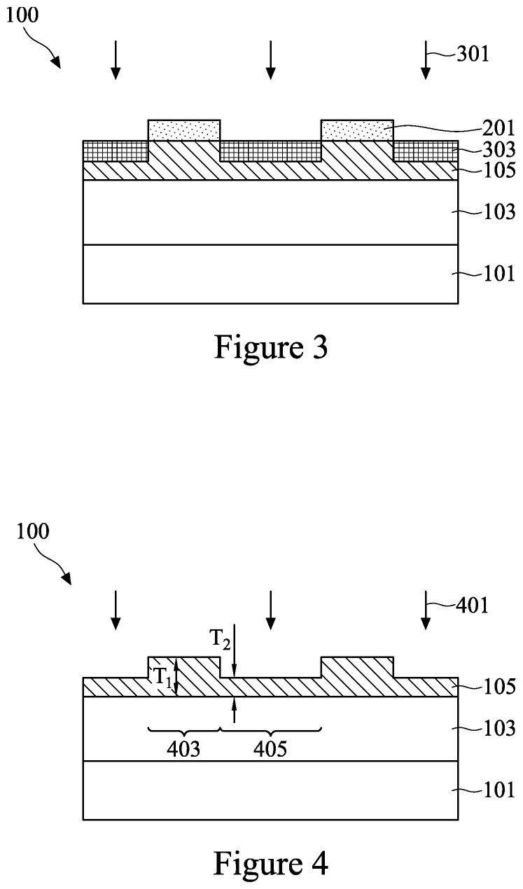

FIG. 3 illustrates a first implantation process (represented in FIG. 3 by the arrows labeled 301) in order to implant first dopants into the non-linear optical material 105 using the first photoresist 201 as a mask to form first implantation regions 303. In an embodiment the first dopants may be dopants which will damage the material of the non-linear optical material 105 and modify the properties of the non-linear optical material 105, such as the refractive index, etching rate, density, etc. of the non-linear optical material 105. As such, in an embodiment the first dopants may be arsenic (As), fluorine (F), nitrogen (N), boron trifluoride (BF₃), combinations of these, or the like. However, any suitable dopant or combination of dopants may be utilized.

In an embodiment the first dopants may be implanted into the non-linear optical material 105 using the first implantation process 301, whereby ions of the desired first dopants are accelerated and directed towards the non-linear optical material 105. The ion implantation process may utilize an accelerator system to accelerate ions of the desired first dopant at a first dosage concentration. As such, while the precise dosage concentration utilized will depend at least in part on the non-linear optical material 105 and the first dopants used, in one embodiment the accelerator system may utilize an energy of between about 100 eV and about 600 eV along with a dosage concentration of about 1E13 atoms/cm² to about 1E15 atoms/cm². However, any suitable parameters may be utilized.

Additionally, the first dopants may be implanted perpendicular to the non-linear optical material 105 or else at, e.g., an angle of between about 0° and about 60°, from perpendicular to the non-linear optical material 105 and may be implanted at a temperature of between about −20° C. and about 100° C. Further, in an embodiment the first dopants may be implanted within the non-linear optical material 105 to a concentration of between about 5E18 atom/cm² and about 1E20 atom/cm². However, any suitable parameters may be utilized.

The first implantation process 301 may be performed by any suitable number of implantations. For example, in one embodiment two separate implantations may be performed in order to implant the first dopants into the non-linear optical material 105, or more than two implants may be utilized. In other embodiments, a single implant may be performed, for example, in which the first substrate 101 is rotated during the single implantation. Any suitable number of implants may be utilized, and all such implants are fully intended to be included within the scope of the embodiments.

By implanting the first dopants into the non-linear optical material 105, the damage done to the non-linear optical material 105 will modify the physical properties of the non-linear optical material 105. For example, in some embodiments the implanting the first dopants helps to increase the etching rate of the non-linear optical material 105 during subsequent etching processes (described further below with respect to FIG. 4). In particular, the damage done by the first implantation process 301 allows subsequent etching solutions to penetrate into the non-linear optical material 105 instead of remaining only on a surface of the non-linear optical material 105. As such, with a larger surface area of contact, the etching solutions will remove the material of the non-linear optical material 105 at the first implantation regions 303 at a greater rate than if the first implantation process 301 is not performed.

FIG. 4 illustrates a first etching process (represented in FIG. 4 by the arrows labeled 401) that is used to remove the first implantation region 303 from the non-linear optical material 105 to shape the non-linear optical material 105 and, e.g., form waveguides. In an embodiment the first etching process 401 may be one or more wet etching processes which use the first photoresist 201 as a mask. In other embodiments the first etching process 401 may be one or more dry etching processes. However, any suitable process may be utilized.

During the first etching process 401, the etching may continue to remove the first implantation regions 303 until the underlying material of the non-linear optical material 105 has been exposed. Once exposed, the non-implanted portions of the non-linear optical material 105 (e.g., those portions of the non-linear optical material 105 that have not undergone a material change) will react at a lower rate, thereby operating as a natural etch stop layer during the removal of the first implantation regions 303.

Once the first etching process 401 has been completed, the non-linear optical material 105 may have a first portion 403 with a first thickness T₁ and a second portion 405 with a second thickness T2 less than the first thickness T₁. In an embodiment the first thickness T1 may be between about 0.3 μm and about 1 μm, and the second thickness T2 may be between about 0.1 μm and about 0.7 μm. However, any suitable thicknesses may be utilized.

Additionally, if there is any remaining portions of the first photoresist 201 after the first etching process 401, the remaining portions of the first photoresist 201 may be removed. In a particular embodiment in which the first photoresist 201 is a bi-layer photoresist comprising a layer of amorphous silicon and an overlying layer of photosensitive material, the removal may be initiated by stripping the photosensitive material using an ashing or wet etching process. Once the photosensitive material has been removed, the amorphous silicon may be planarized using, e.g., a chemical mechanical polishing process and then the amorphous silicon may be removed using one or more etching processes. However, any suitable steps or combination of steps may be utilized to remove the first photoresist 201.

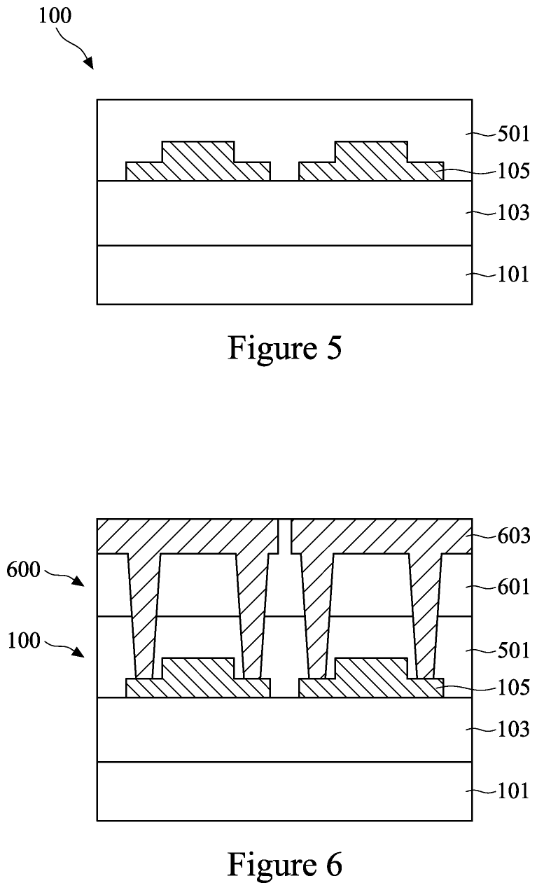

FIG. 5 illustrates a deposition of a first cladding material 501 over the non-linear optical material 105 and, if present, the first optical components. In an embodiment the first cladding material 501 may be a dielectric material that separates the non-linear optical material 105 and other individual components of the first active layer from each other and from the overlying structures and can additionally serve as another portion of cladding material that surrounds the non-linear optical material 105. In an embodiment the first cladding material 501 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the first cladding material 501 has been deposited, the material may be planarized using, e.g., a chemical mechanical polishing process in order to either planarize a top surface of the first cladding material 501 (in embodiments in which the first cladding material 501 is intended to fully cover the underlying devices) or else planarize the first cladding material 501 with top surfaces of the non-linear optical material 105 and/or the first optical components. However, any suitable material and method of manufacture may be used.

FIG. 6 illustrates a formation of a first dielectric material 601 over the first cladding material 501, and a formation of conductive structures 603 to form an optical phase shifter 600. In an embodiment the first dielectric material 601 may be similar to the first cladding material 501, such as by being silicon oxide, silicon nitride, germanium oxide, germanium nitride, combinations of these, or the like, formed using a deposition method such as chemical vapor deposition, atomic layer deposition, physical vapor deposition, combinations of these, or the like. However, any suitable material may be formed.

Once the first dielectric material 601 has been deposited, the conductive structures 603 may be formed through the first dielectric material 601 and the first cladding material 501 in order to make electrical contact with the non-linear optical material 105. In an embodiment the conductive structures 603 may be formed through any suitable process such as deposition, damascene, dual damascene, etc. For example, in some embodiments the conductive structures 603 are formed using a damascene or dual damascene process, whereby an opening is formed within the first dielectric material 601 and the first cladding material 501, and the opening is filled with one or more conductive materials, such as barrier layers and fill materials such as copper, tungsten, combinations of these, or the like. However, any suitable method may be utilized.

Of course, while the conductive structures 603 may be formed as described above using a damascene or dual damascene structure, this description is intended to be illustrative and is not intended to be limiting to the embodiments. For example, in other embodiments the conductive structures 603 may be initially formed by forming lower portions prior to the deposition of the first cladding material 501 using, e.g., a seed layer deposition, photolithographic masking, and plating process. Once the lower portions have been formed, the first cladding material 501 may be deposited, and upper portions of the conductive structures 603 may be formed using either a similar process or else through a damascene or dual damascene process. Any suitable process may be used to make electrical connections to the underlying non-linear optical material 105, and all such processes are fully intended to be included within the scope of the embodiments.

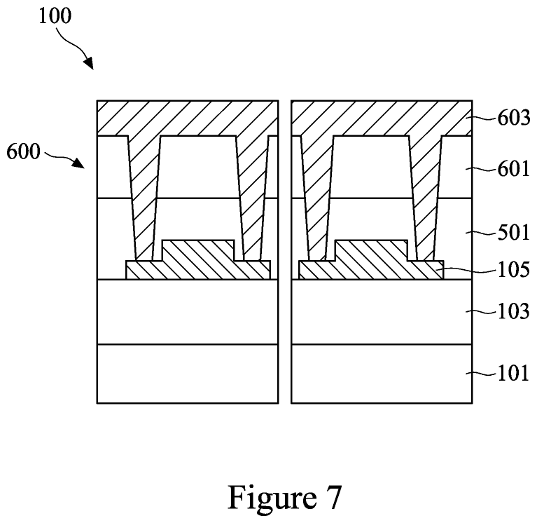

FIG. 7 illustrates that, once the first optical device 100 has been manufactured, the first optical device 100 may be singulated in preparation for placement. In an embodiment the singulation may be performed by using a saw blade (not separately illustrated) to slice through the first substrate 101 and overlying structures. However, as one of ordinary skill in the art will recognize, utilizing a saw blade for the dicing is merely one illustrative embodiment and is not intended to be limiting. Any method for performing the singulation, such as utilizing one or more etches, may be utilized. These methods and any other suitable methods may be utilized to singulate the structure.

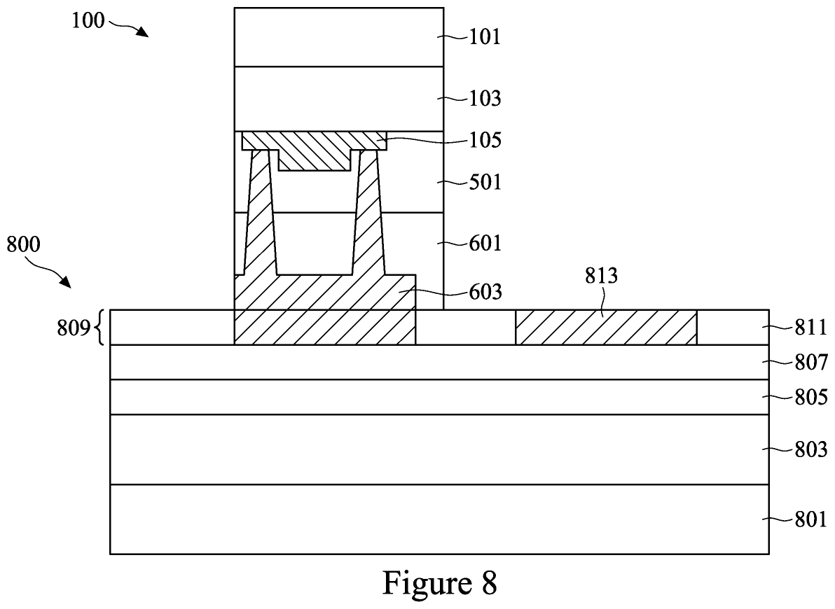

FIG. 8 illustrates a bonding of the first optical device 100 to a second optical device 800. In an embodiment the second optical device 800 is an optical interposer and comprises a second substrate 801, a second insulator layer 803, and a second layer 805 of second optical components (not separately illustrated in FIG. 8). In an embodiment, at a beginning of the manufacturing process of the second optical device 800, the second substrate 801, the second insulator layer 803, and the layer of material for the second active layer of second optical components may collectively be part of a silicon-on-insulator (SOI) substrate. Looking first at the second substrate 801, the second substrate 801 may be a semiconductor material such as silicon or germanium, a dielectric material such as glass, or any other suitable material that allows for structural support of overlying devices. In a particular embodiment the second substrate 801 may be a 12″ silicon wafer, although any suitable material and any suitable shape may be utilized.

The second insulator layer 803 may be a dielectric layer that separates the second substrate 801 from the overlying second active layer and can additionally, in some embodiments, serve as a portion of cladding material that surrounds the subsequently manufactured second optical components (discussed further below). In an embodiment the second insulator layer 803 may be silicon oxide, silicon nitride, germanium oxide, germanium nitride, combinations of these, or the like, formed using a method such as implantation (e.g., to form a buried oxide (BOX) layer) or else may be deposited onto the second substrate 801 using a deposition method such as chemical vapor deposition, atomic layer deposition, physical vapor deposition, combinations of these, or the like. However, any suitable material and method of manufacture may be used.

The material for the second active layer is initially (prior to patterning) a conformal layer of material that will be used to begin manufacturing the second active layer of the second optical components. In an embodiment the material for the second active layer may be a translucent material that can be used as a core material for the desired second optical components, such as a semiconductor material such as silicon, germanium, silicon germanium, combinations of these, or the like, while in other embodiments the material for the second active layer may be a dielectric material such as silicon nitride or the like, although in other embodiments the material for the second active layer may be III-V materials, lithium niobate materials, or polymers. In embodiments in which the material of the second active layer is deposited, the material for the second active layer may be deposited using a method such as epitaxial growth, chemical vapor deposition, atomic layer deposition, physical vapor deposition, combinations of these, or the like. In other embodiments in which the second insulator layer 803 is formed using an implantation method, the material of the second active layer may initially be part of the second substrate 801 prior to the implantation process to form the second insulator layer 803. However, any suitable materials and methods of manufacture may be utilized to form the material of the second active layer.

Once the material for the second active layer is ready, the second optical components for the second active layer are manufactured using the material for the second active layer. In embodiments the second optical components of the second active layer may include such components as optical waveguides (e.g., ridge waveguides, rib waveguides, buried channel waveguides, diffused waveguides, etc.), couplers (e.g., grating couplers, edge couplers, etc.), directional couplers, optical modulators (e.g., Mach-Zehnder silicon-photonic switches, microelectromechanical switches, micro-ring resonators, etc.), amplifiers, multiplexors, demultiplexers, optical-to-electrical converters (e.g., P-N junctions), electrical-to-optical converters, lasers, combinations of these, or the like. However, any suitable second optical components may be used.

To begin forming the second active layer of second optical components from the initial material, the material for the second active layer may be patterned into the desired shapes for the second active layer of second optical components. In an embodiment the material for the second active layer may be patterned using, e.g., one or more photolithographic masking and etching processes. However, any suitable method of patterning the material for the second active layer may be utilized. For some of the second optical components, such as waveguides or edge couplers, the patterning process may be all or at least most of the manufacturing that is used to form these second optical components.

For those components that utilize further manufacturing processes, such as Mach-Zehnder silicon-photonic switches that utilize resistive heating elements, additional processing may be performed either before or after the patterning of the material for the second active layer. For example, implantation processes, additional deposition and patterning processes for different materials (e.g., resistive heating elements, III-V materials for converters), combinations of all of these processes, or the like, can be utilized to help further the manufacturing of the various desired second optical components. In a particular embodiment, an epitaxial deposition of a semiconductor material such as germanium (used, e.g., for electricity/optics signal modulation and transversion) may be performed on a patterned portion of the material of the second active layer. In such an embodiment the semiconductor material may be epitaxially grown in order to help manufacture, e.g., a photodiode for an optical-to-electrical converter. All such manufacturing processes and all suitable second optical components may be manufactured, and all such combinations are fully intended to be included within the scope of the embodiments.

Once the individual second optical components of the second active layer have been formed, a first insulating layer may be deposited to cover the second optical components and provide additional cladding material. In an embodiment the first insulating layer may be a dielectric layer that separates the individual components of the second active layer from each other and from the overlying structures and can additionally serve as another portion of cladding material that surrounds the second optical components. In an embodiment the first insulating layer may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the first insulating layer has been deposited, the material may be planarized using, e.g., a chemical mechanical polishing process in order to either planarize a top surface of the first insulating layer (in embodiments in which the first insulating layer is intended to fully cover the second optical components) or else planarize the first insulating layer with top surfaces of the second optical components. However, any suitable material and method of manufacture may be used.

Once the second optical components of the second active layer have been manufactured and the first insulating layer has been formed, first metallization layers 807 are formed in order to electrically connect the second active layer of second optical components to control circuitry, to each other, and to subsequently attached devices. In an embodiment the first metallization layers 807 are formed of alternating layers of dielectric and conductive material and may be formed through any suitable processes (such as deposition, damascene, dual damascene, etc.). In particular embodiments there may be multiple layers of metallization used to interconnect the various second optical components, but the precise number of first metallization layers 807 is dependent upon the design of the second optical device 800.

Additionally, during the manufacture of the first metallization layers 807, one or more third optical components may be formed as part of the first metallization layers 807. In some embodiments the third optical components of the first metallization layers 807 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexers, optical-to-electrical converters (e.g., P-N junctions), electrical-to-optical converters, lasers, combinations of these, or the like. However, any suitable optical components may be used for the one or more third optical components.

In an embodiment the one or more third optical components may be formed by initially depositing a material for the one or more third optical components. In an embodiment the material for the one or more third optical components may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more third optical components has been deposited or otherwise formed, the material may be patterned into the desired shapes for the one or more third optical components. In an embodiment the material of the one or more third optical components may be patterned using, e.g., one or more photolithographic masking and etching processes. However, any suitable method of patterning the material for the one or more third optical components may be utilized.

For some of the one or more third optical components, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more third optical components. For example, implantation processes, additional deposition and patterning processes for different materials, combinations of all of these processes, or the like, and can be utilized to help further the manufacturing of the various desired one or more third optical components. All such manufacturing processes and all suitable third optical components may be manufactured, and all such combinations are fully intended to be included within the scope of the embodiments.

Once the one or more third optical components of the first metallization layers 807 have been manufactured, a first bonding layer 809 is formed over the first metallization layers 807. In an embodiment, the first bonding layer 809 may be used for a dielectric-to-dielectric and metal-to-metal bond. In accordance with some embodiments, the first bonding layer 809 is formed of a bonding dielectric material 811 such as silicon oxide, silicon nitride, or the like. The bonding dielectric material 811 may be deposited using any suitable method, such as CVD, high-density plasma chemical vapor deposition (HDPCVD), PVD, atomic layer deposition (ALD), or the like. However, any suitable materials and deposition processes may be utilized.

Once the bonding dielectric material 811 has been formed, first openings in the bonding dielectric material 811 are formed to expose conductive portions of the underlying layers in preparation to form first bond pads 813 within the first bonding layer 809. Once the first openings have been formed within the bonding dielectric material 811, the first openings may be filled with a seed layer and a plate metal to form the first bond pads 813 within the bonding dielectric material 811. The seed layer may be blanket deposited over top surfaces of the bonding dielectric material 811 and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the bonding dielectric material 811 and sidewalls of the openings and the second openings before the seed layer. The barrier layer may comprise titanium, titanium nitride, tantalum, tantalum nitride, or the like.

Following the filling of the first openings, a planarization process, such as a CMP, is performed to remove excess portions of the seed layer and the plate metal, forming the first bond pads 813 within the first bonding layer 809. In some embodiments a bond pad via (not separately illustrated) may also be utilized to connect the first bond pads 813 with underlying conductive portions and, through the underlying conductive portions, connect the first bond pads 813 with the first metallization layers 807.

FIG. 8 further illustrates that, once the first bond pads 813 have been formed, the first optical device 100 and the second optical device 800 are bonded together in a face-to-face configuration. In a particular embodiment which utilizes a dielectric-to-dielectric and a metal-to-metal bonding process, the process may be initiated by activating the surfaces of the first optical device 100 and the second optical device 800. Activating the top surfaces of the first optical device 100 and the second optical device 800 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the first optical device 100 and the second optical device 800.

After the activation process the first optical device 100 and the second optical device 800 may be cleaned using, e.g., a chemical rinse, and then the first optical device 100 is aligned and placed into physical contact with the second optical device 800. The first optical device 100 and the second optical device 800 are then subjected to a thermal treatment and contact pressure to bond the first optical device 100 and the second optical device 800. For example, the first optical device 100 and the second optical device 800 may be subjected to a pressure of about 200 kPa or less, and a temperature between about 25° C. and about 250° C. to fuse the first optical device 100 and the second optical device 800. The first optical device 100 and the second optical device 800 may then be subjected to a temperature at or above the eutectic point for material of the conductive structures 603 and the first bond pads 813, e.g., between about 150° C. and about 650° C., to fuse the conductive structures 603 and the first bond pads 813. In this manner, the first optical device 100 and the second optical device 800 forms a dielectric-to-dielectric and metal-to-metal bonded device. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

By utilizing electro-optic materials with a strong Pockels effect, a high-performance optical phase shifter 600 can be obtained. Additionally, such performance may be obtained while maintaining a low propagation loss. Such a high performance optical phase shifter 600, once integrated with other devices, can help to lower propagation losses and create a better performing device.

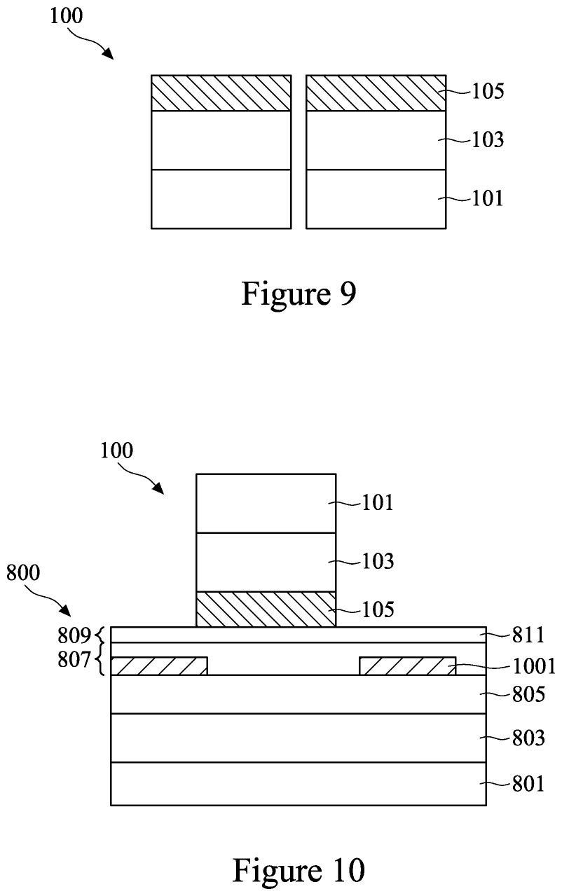

FIGS. 9-17 illustrate another embodiment in which the first optical device 100 is bonded to the second optical device 800. In this embodiment, however, the first optical device 100 is bonded to the second optical device 800 using a back-to-face configuration instead of the face-to-face configuration described above. As such, in this embodiment, once the first substrate 101, the first insulator layer 103, the first active layer of first optical components (not separately illustrated in FIG. 9), and the layer of non-linear optical material 105 have been formed (as described above with respect to FIG. 1), the first substrate 101, the first insulator layer 103, the first active layer of first optical components, and the layer of non-linear optical material 105 are singulated. In an embodiment the singulation may be performed by using a saw blade (not separately illustrated) to slice through the first substrate 101 and overlying structures while the first substrate 101 is on a 12″ dicing frame. In a particular embodiment the first substrate 101 may be singulated into a rectangular shape with a width of 26 mm² and a length of 33 mm². However, as one of ordinary skill in the art will recognize, utilizing a saw blade for the dicing is merely one illustrative embodiment and is not intended to be limiting. Any method for performing the singulation, such as utilizing one or more etches, may be utilized. These methods and any other suitable methods may be utilized to singulate the structure with any desired dimensions.

FIG. 10 illustrates that, once the singulation process has been performed the layer of non-linear optical material 105 is bonded to the second optical device 800 such that the non-linear optical material 105 shares a bonding interface with the second optical device. In this embodiment the second optical device 800 may be as described above with respect to FIG. 8, such as by having the second substrate 801, the second insulator layer 803, the second layer 805, the first metallization layers 807 (with conductive elements 1001 illustrated in FIG. 10), and the bonding dielectric material 811. In this embodiment, the first optical device 100 will be electrically connected to conductive elements 1001 located within the first metallization layers 807. As such, the first bond pads 813 may be omitted, and the first bonding layer 809 will comprise the bonding dielectric material 811 without the first bond pads 813.

In an embodiment the layer of non-linear optical material 105 is bonded to the second optical device 800 using a dielectric-to-dielectric bonding process similar to the process described above with respect to FIG. 8 but without the bonding of the conductive structures 603 and the first bond pads 813. For example, the surfaces of the first optical device 100 and the second optical device 800 are activated, aligned, and placed into physical contact. However, any suitable bonding process may be utilized.

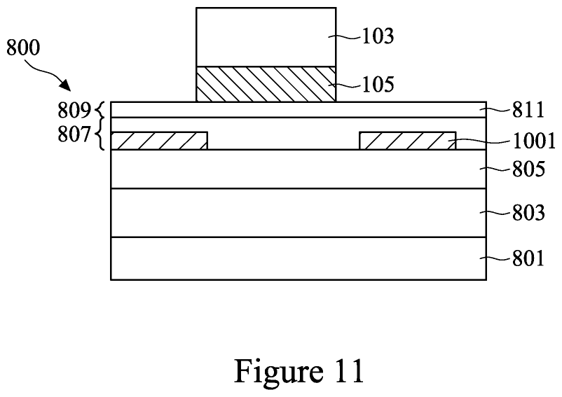

FIG. 11 illustrates that, once the first optical device 100 and the second optical device 800 have been bonded, the first substrate 101 may be removed. In an embodiment the first substrate 101 may be removed using a combination of grinding to remove a bulk amount of the first substrate 101 (e.g., to leave behind about 20 μm of material) followed by one or more etching processes such as a dry etch to remove any remaining portion of the first substrate 101. However, any suitable process or combination of processes may be utilized.

Optionally at this point, if desired, a gap fill material (not separately illustrated in FIG. 11) may be deposited over and around the first insulator layer 103 and the non-linear optical material 105. In an embodiment the gap fill material may be a cladding or insulating material such as silicon oxide, and may be deposited using a deposition process such as chemical vapor deposition, physical vapor deposition, atomic layer deposition, combinations of these, or the like, and the gap fill material may be planarized using a process such as chemical mechanical polishing. However, any suitable materials, methods of formation, and planarization may be utilized.

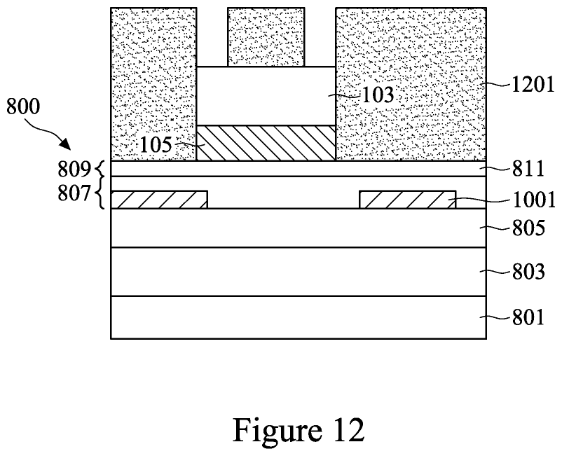

FIG. 12 illustrates a placement of a second photoresist 1201 over and around the now exposed first insulator layer 103. In an embodiment the second photoresist 1201 may be one or more layers of masks, wherein at least one layer is a photosensitive material (e.g., a bi-layer photoresist comprising a layer of amorphous silicon and a layer of photosensitive material). Once in place the photosensitive material is imaged and developed, underlying layers are patterned, and the remaining portions become the patterned second photoresist 1201.

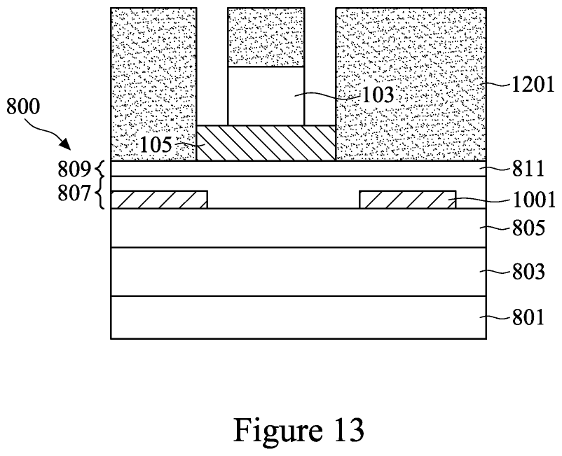

FIG. 13 illustrates a patterning of the first insulator layer 103 using the second photoresist 1201 as a mask. In an embodiment the first insulator layer 103 is patterned using one or more anisotropic etching processes, such as reactive ion etching processes that stops on the non-linear optical material 105. However, any suitable etching or other patterning process may be utilized.

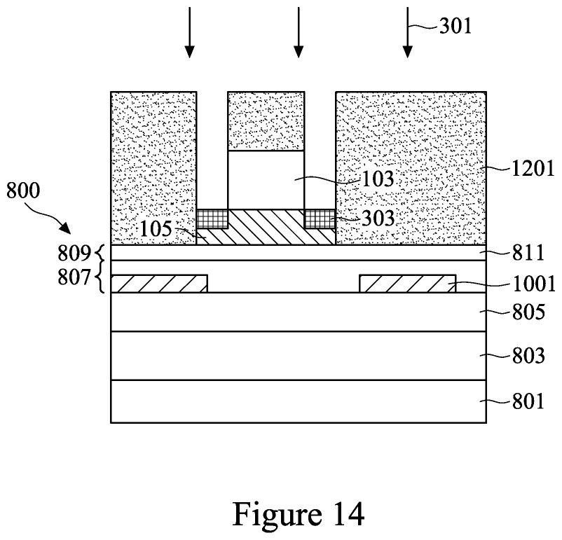

FIG. 14 illustrates using the first implantation process 301 in order to implant the first dopants and form the first implantation regions 303 within the non-linear optical material 105. In an embodiment the first implantation process 301 and the first implantation regions 303 may be performed as described above with respect to FIG. 3. However, any suitable implantation process may be performed.

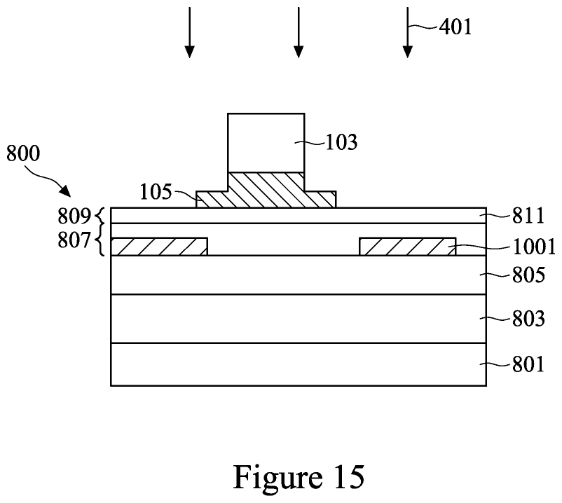

FIG. 15 illustrates a removal of the first implantation regions 303 and the second photoresist 1201. In an embodiment the first implantation regions 303 may be removed using the first etching process 401 as described above with respect to FIG. 4. However, any suitable removal processes may be utilized.

Once the first implantation regions 303 have been removed, the second photoresist 1201 may be removed. In a particular embodiment in which the second photoresist 1201 is a bi-layer photoresist comprising a layer of amorphous silicon and an overlying layer of photosensitive material, the removal may be initiated by stripping the photosensitive material using an ashing or wet etching process. Once the photosensitive material has been removed, the amorphous silicon may be planarized using, e.g., a chemical mechanical polishing process and then the amorphous silicon may be removed using one or more etching processes. However, any suitable steps or combination of steps may be utilized to remove the second photoresist 1201.

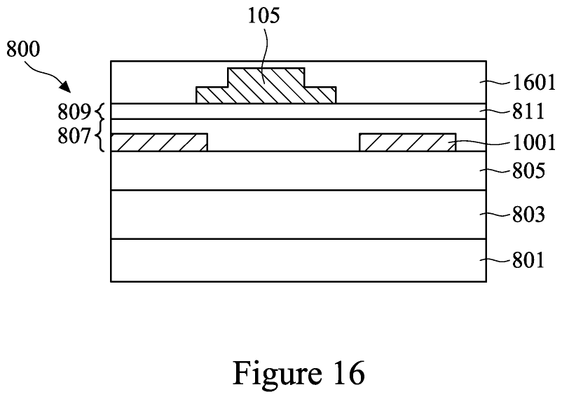

FIG. 16 illustrates that, once the non-linear material 105 has been patterned, and in embodiments in which the gap fill material (discussed above with respect to FIG. 11) is not utilized, a third insulator layer 1601 may be deposited over the patterned non-linear optical material 105. In an embodiment the third insulator layer 1601 may be a dielectric material such as silicon oxide, silicon nitride, silicon oxynitride, combinations of these, or the like, deposited using a deposition process such as chemical vapor deposition, physical vapor deposition, atomic layer deposition, combinations of these, or the like. However, any suitable material and any suitable deposition process may be utilized.

Additionally, once the third insulator layer 1601 has been deposited, the third insulator layer 1601 may be planarized and/or thinned. In an embodiment the third insulator layer 1601 may be planarized using, e.g., a chemical mechanical planarization process. However, any other suitable process, such as a grinding process or even one or more etching processes, may be utilized.

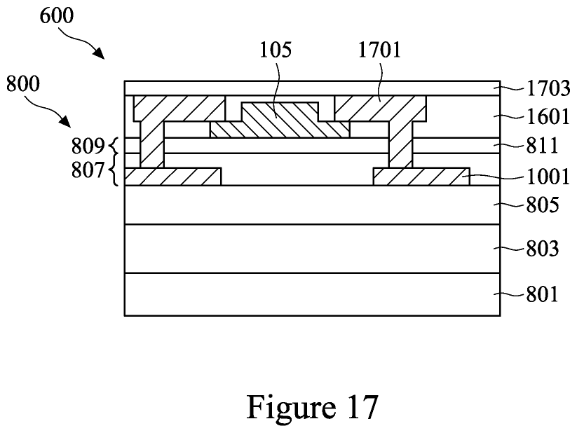

FIG. 17 illustrates that, once the third insulator layer 1601 has been formed, electrical connections 1701 may be formed between the non-linear optical material 105 and the conductive elements 1001 within the first metallization layers 807 to form the optical phase shifter 600. In an embodiment the electrical connections 1701 may be formed using, e.g., a damascene or dual damascene process. For example, openings may be formed through the third insulator layer 1601 and into the first metallization layers 807 to expose portions of the non-linear optical material 105 and portions of the conductive elements 1001. In an embodiment the openings may be formed using one or more photolithographic masking and etching processes. However, any suitable methods may be used to form the openings.

Once the openings have been formed, a barrier layer and a seed layer may be deposited to line the openings, and a plating process may be used to fill and/or overfill the openings with a conductive material such as copper, tungsten, or the like. As such, the electrical connections 1701 extend across the bonding interface and provides electrical connection between the non-linear optical material 105 and the underlying conductive elements 1001. Additionally, once filled, the conductive material may be planarized with the third insulator layer 1601 using, e.g., a chemical mechanical polishing process.

FIG. 17 additionally illustrates that, once the electrical connections 1701 have been formed, a fourth insulator layer 1703 may be deposited and planarized in order to cover and protect the electrical connections 1701. In an embodiment the fourth insulator layer 1703 may be formed using similar processes and similar materials as the third insulator layer 1601, described above with respect to FIG. 16. However, any suitable methods and materials may be utilized.

By utilizing the materials and properties presented herein, a high performance optical phase shifter 600 with low propagation loss may be obtained. Further, by using the methods presented, the high performance optical phase shifter 600 may be integrated into a photonic device using a wide variety of processes, thereby allowing for the optical phase shifter 600 to be integrated with the best manufacturing options.

In accordance with an embodiment, a method of manufacturing an optical device includes: depositing a non-linear material; forming an implantation region within the non-linear material; removing the implantation region over a first portion of the non-linear material; and forming an electrode to the first portion. In an embodiment the non-linear material is LiNbO₃. In an embodiment the non-linear material is BaTiO₃. In an embodiment the non-linear material is lead zirconate titanate. In an embodiment the forming the implantation region implants arsenic. In an embodiment the forming the implantation region implants fluorine. In an embodiment the forming the implantation region implants nitrogen.

In accordance with another embodiment, a method of manufacturing a semiconductor device includes: depositing a non-linear material onto a substrate; modifying an etching characteristics of a first region of the non-linear material; etching the first region and leaving a non-etched region; and forming an electrode to the non-etched region. In an embodiment the method further includes, after the forming the electrodes, bonding the electrodes to an optical device. In an embodiment the method further includes prior to the modifying the etching characteristics, bonding the non-linear material to an optical device, wherein the forming electrodes forms the electrodes at least partially into the optical device. In an embodiment the modifying the etching characteristics further comprises implanting a first dopant into the first region. In an embodiment the first dopant is fluorine. In an embodiment the first dopant is arsenic. In an embodiment the non-linear material is lithium niobate.

In accordance with yet another embodiment, an optical device includes: a non-linear material over a substrate; a first electrode adjacent to a first side of the non-linear material; and a second electrode adjacent to a second side of the non-linear material. In an embodiment the non-linear material is LiNbO₃. In an embodiment the non-linear material is BaTiO₃. In an embodiment the non-linear material is lead zirconate titanate. In an embodiment the first electrode is electrically connected to a via, the via extending from one side of a bonding interface to a second side of the bonding interface. In an embodiment the non-linear material shares a bonding interface with an optical device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an optical device, the method comprising:
depositing a non-linear material;
forming an implantation region within the non-linear material;
removing the implantation region over a first portion of the non-linear material; and
forming an electrode to the first portion.

2. The method of claim 1, wherein the non-linear material is LiNbO₃.

3. The method of claim 1, wherein the non-linear material is BaTiO₃.

4. The method of claim 1, wherein the non-linear material is lead zirconate titanate.

5. The method of claim 1, wherein the forming the implantation region implants arsenic.

6. The method of claim 1, wherein the forming the implantation region implants fluorine.

7. The method of claim 1, wherein the forming the implantation region implants nitrogen.

8. A method of manufacturing a semiconductor device, the method comprising:
depositing a non-linear material onto a substrate;
modifying an etching characteristics of a first region of the non-linear material;
etching the first region and leaving a non-etched region; and
forming an electrode to the non-etched region.

9. The method of claim 8, further comprising, after the forming the electrodes, bonding the electrodes to an optical device.

10. The method of claim 8, further comprising prior to the modifying the etching characteristics, bonding the non-linear material to an optical device, wherein the forming electrodes forms the electrodes at least partially into the optical device.

11. The method of claim 8, wherein the modifying the etching characteristics further comprises implanting a first dopant into the first region.

12. The method of claim 11, wherein the first dopant is fluorine.

13. The method of claim 11, wherein the first dopant is arsenic.

14. The method of claim 8, wherein the non-linear material is lithium niobate.

15. An optical device comprising:
a non-linear material over a substrate;
a first electrode adjacent to a first side of the non-linear material; and
a second electrode adjacent to a second side of the non-linear material.

16. The optical device of claim 15, wherein the non-linear material is LiNbO₃.

17. The optical device of claim 15, wherein the non-linear material is BaTiO₃.

18. The optical device of claim 15, wherein the non-linear material is lead zirconate titanate.

19. The optical device of claim 15, wherein the first electrode is electrically connected to a via, the via extending from one side of a bonding interface to a second side of the bonding interface.

20. The optical device of claim 15, wherein the non-linear material shares a bonding interface with an optical device.
